(19) United States
(12) Patent Application Publication
(10) Pub. No.: US 2021/0280761 A1
(43) Pub. Date: Sep. 9, 2021

(54) SEMICONDUCTOR MODULE, TEMPERATURE CONTROL SYSTEM INCLUDING THE SAME, AND TEMPERATURE CONTROL METHOD

(71) Applicant: SK hynix Inc., Gyeonggi-do (KR)

(72) Inventors: Gyung Jin KIM, Gyeonggi-do (KR); Jeong Hun LEE, Gyeonggi-do (KR)

(21) Appl. No.: 16/923,862

(22) Filed: Jul. 8, 2020

(30) Foreign Application Priority Data
Mar. 6, 2020 (KR) 10-2020-0028119

(51) Int. Cl. H01L 35/30; H01L 35/04

(52) U.S. Cl. CPC H01L 35/30; H01L 35/04

(57) ABSTRACT

A semiconductor module includes a substrate, a semiconductor package disposed over the substrate, a Peltier element disposed over the semiconductor package and having a heat absorbing portion and a heat generating portion, the heat absorbing portion being adjacent to the semiconductor package and the heat generating portion being adjacent to a cooling element, and the cooling element disposed over the Peltier element.

### CROSS-REFERENCE TO RELATED APPLICATION

This application claims priority under 35 U.S.C. § 119 to Korean Patent Application No. 10-2020-0028119 filed on Mar. 6, 2020, which is incorporated herein by reference in its entirety.

### BACKGROUND

### 1. Technical Field

This patent document relates to a semiconductor technology, and more particularly, to a semiconductor module, a temperature control system including the same, and a temperature control method.

### 2. Related Art

Electronic products become smaller and they also require high-capacity data processing. Accordingly, a degree of integration of semiconductor chips or modules used in such electronic products is gradually increasing.

However, due to the increase in the degree of integration of semiconductor chips or modules, the heat which is generated by these products is also increasing and may cause various problems such as malfunction, performance deterioration, or shortened life in integrated circuits. Therefore, there exists a need to develop improved technologies for cooling new semiconductor chips or modules which are more densely packed in memory devices than in existing devises.

Also, new systems such as quantum computers require cryogenic memories, i.e., memories operating at very low cryogenic temperatures. Hence, there is a need to develop improved technologies for cooling semiconductor chips or modules of such quantum computers to a cryogenic temperature such as, for example, to a cryogenic temperature of −196° C.

### SUMMARY

Various embodiments of the present disclosure are directed to a semiconductor module which can be efficiently and locally cooled and easily implemented. Various embodiments also relate to a temperature control system including the semiconductor module, and a temperature control method thereof.

In an embodiment, a semiconductor module may include: a semiconductor package disposed over a substrate; a Peltier element disposed over the semiconductor package and having a heat absorbing portion and a heat generating portion, the heat absorbing portion being adjacent to the semiconductor package and the heat generating portion being adjacent to a cooling element; and the cooling element disposed over the Peltier element.

In an embodiment, a temperature control system may include: a semiconductor module; and a temperature control device controlling a temperature of the semiconductor module, wherein the semiconductor module comprises: a substrate; a semiconductor package disposed over the substrate; a Peltier element disposed over the semiconductor package and having a heat absorbing portion and a heat generating portion, the heat absorbing portion being adjacent to the semiconductor package and the heat generating portion being adjacent to a cooling element; and the cooling element disposed over the Peltier element.

In an embodiment, a temperature control method for controlling a temperature of a semiconductor module, which includes a Peltier element disposed over a semiconductor package and having a heat absorbing portion adjacent to the semiconductor package and a heat generating portion adjacent to a cooling element, and the cooling element disposed over the Peltier element, may include: receiving temperature information of the semiconductor package from the semiconductor module; determining whether a temperature of the semiconductor package exceeds a target cooling temperature according to the received temperature information; when the temperature of the semiconductor package exceeds the target cooling temperature, increasing a flow rate of a cooling liquid supplied to the cooling element, increasing a power applied to the Peltier element, or both; and when the temperature of the semiconductor package does not exceed the target cooling temperature, reducing the flow rate of the cooling liquid supplied to the cooling element, reducing the power applied to the Peltier element, or both.

In an embodiment, a semiconductor module may include: a substrate including a power circuit; a semiconductor package disposed on a first substrate; a Peltier element having a heat absorbing portion and a heat generation portion; a cooling element; and a second substrate physically separated from the first substrate and electrically connected with the first substrate for electrically connecting the semiconductor module to an external component, wherein the heat absorbing portion is in contact with the semiconductor package, and the heat generating portion is in contact with the cooling element, and a target cooling temperature of the semiconductor package is controlled according to a flow rate of a cooling liquid flowing through the cooling element or a power supplied to the Peltier element from the power circuit.

These and other features and advantages will become better understood from the detailed description of specific embodiments in conjunction with the following drawings.

### BRIEF DESCRIPTION OF THE DRAWINGS

FIG. 1 is a simplified schematic illustrating a temperature control system including a semiconductor module and a temperature control device according to an embodiment of the present disclosure.

FIG. 2 is a flow chart of a temperature control method of the temperature control device of the system of FIG. 1.

FIG. 3 is a simplified schematic illustrating a temperature control system according to another embodiment of the present disclosure.

FIG. 4 is a simplified schematic illustrating a temperature control system according to yet another embodiment of the present disclosure.

FIG. 5 is simplified schematic illustrating a temperature control system according to another embodiment of the present disclosure.

### DETAILED DESCRIPTION

Hereinafter, various embodiments of the present disclosure will be described in detail with reference to the accompanying drawings.

The drawings may not be necessarily to scale and in some instances, proportions of at least some of structures in the drawings may have been exaggerated in order to clearly illustrate certain features of the described examples or embodiments. In presenting a specific example in a drawing or description having two or more layers in a multi-layer structure, the relative positioning relationship of such layers or the sequence of arranging the layers as shown reflects a particular embodiment for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

It should be understood that the drawings are simplified schematic illustrations of the described devices and may not include well known details for avoiding obscuring the features.

It should also be noted that features present in one embodiment may be used with one or more features of another embodiment without departing from the scope of the disclosure.

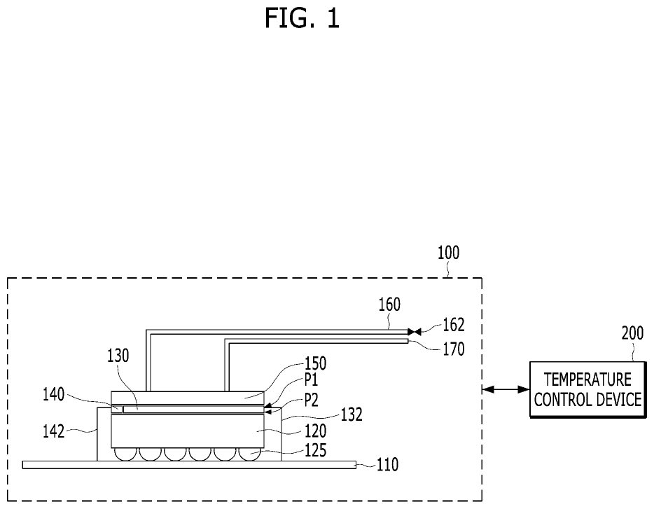

FIG. 1 is a simplified schematic illustrating a temperature control system according to an embodiment of the present disclosure.

Referring to FIG. 1, a temperature control system according to an embodiment of the present disclosure may include a semiconductor module 100 and a temperature control device 200 operably coupled to the semiconductor module for controlling a temperature of the semiconductor module 100.

The semiconductor module 100 may include a substrate 110, a semiconductor package 120 disposed over the substrate 110, a Peltier element 130 and a temperature sensor 140 disposed over the semiconductor package 120. The temperature sensor 140 is adjacent to the Peltier element 130 and at the same level with the Peltier element 130. The semiconductor module may also include a cooling element 150 disposed over the Peltier element 130 and the temperature sensor 140. A cooling liquid supply pipe 160 and a cooling liquid recovery pipe 170 may be connected to the cooling element 150.

The substrate 110 may be a semiconductor package substrate having one or more circuits and/or wiring structures for electric signal transmission. For example, the substrate 110 may be a printed circuit board (PCB).

The semiconductor package 120 may be disposed over the substrate 110. In this embodiment, although specific configurations of the semiconductor package 120 are not illustrated, the semiconductor package 120 may be implemented in various forms and may include one or more semiconductor chips. For example, when the semiconductor package 120 includes a plurality of semiconductor chips, the plurality of semiconductor chips may be stacked in a direction parallel to a surface of the substrate 110 or in a direction perpendicular to the surface of the substrate 110. Furthermore, the semiconductor package 120 may further include a molding layer encapsulating the semiconductor chip, a base substrate providing a connection between the semiconductor chip and the substrate 110, or the like.

The semiconductor chip included in the semiconductor package 120 may be a memory chip. For example, the semiconductor package 120 may include a volatile memory such as a DRAM (Dynamic Random Access Memory) or an SRAM (Static RAM), a nonvolatile memory such as a NAND flash, an RRAM (Resistive RAM), a PRAM (Phase-change RAM), an MRAM (Magneto resistive RAM), or an FRAM (Ferroelectric RAM), or the like. In this case, the semiconductor module 100 of the present embodiment may be a memory module.

The semiconductor package 120 may be electrically connected to the substrate 110 through a connection terminal 125. The connection terminal 125 may include a plurality of solder balls as shown. However, the present disclosure is not limited to this, and various conductive terminals such as bumps, or the like, may be used as the connection terminal 125.

In an embodiment, the Peltier element 130 may be a thermoelectric element using a Peltier effect in which, when current is passed through a junction of two types of metals, heat is transferred from one of the metals to the other one of the metals. When power is applied to this thermoelectric element, heat moves from a heat absorbing portion to a heat generating portion. Therefore, a temperature of the heat absorbing portion may decrease and a temperature of the heat generating portion may increase. In this embodiment, the Peltier element 130 may include a heat generating portion P1 and a heat absorbing portion P2. The heat generating portion P1 may be disposed adjacent to the cooling element 150, and the heat absorbing portion P2 may be disposed adjacent to the semiconductor package 120. Accordingly, the Peltier element 130 may serve to lower a temperature of the semiconductor package 120 together with the cooling element 150, that is, to cool the semiconductor package 120. This will be described in more detail later.

In the embodiment of FIG. 1, the heat absorbing portion P2 of the Peltier element 130, may contact an upper surface of the semiconductor package 120. For reference, contact may mean both direct contact and indirect contact through other materials. For example, although not shown, an adhesive material or a thermal interface material (TIM) may be further interposed between the Peltier element 130 and the semiconductor package 120.

The Peltier element 130 may be connected to the substrate 110 through an interconnector 132 and be supplied with a power from the substrate 110. To this end, the substrate 110 may include a power supply circuit (not shown). The interconnector 132 may be any suitable wire such as, for example, a bonding wire. The interconnector 132 may have one end connected to the Peltier element 130 and the other end connected to the substrate 110. However, the present disclosure is not limited to this, and various types of electrical interconnectors may be used as the interconnector 132.

In the present embodiment, the Peltier element 130 may be formed to overlap with only a portion of the upper surface of the semiconductor package 120 leaving exposed a portion of the upper surface of the semiconductor package. This exposed portion provides a space in which the temperature sensor 140 is to be positioned or formed. However, in another embodiment, the temperature sensor 140 may be omitted and the Peltier element 130 may overlap the entire upper surface of the semiconductor package 120. In this embodiment, an overlapping area of the Peltier element 130 and the semiconductor package 120 may be larger than an overlapping area of the temperature sensor 140 and the semiconductor package 120. This is because a cooling effect by the Peltier element 130 increases as the overlapping area increases.

The temperature sensor 140 may sense and/or measure the temperature of the semiconductor package 120. Any suitable sensor may be used. For example, the temperature sensor 140 may include a thermocouple. The thermocouple may refer to an element that bonds two types of metals and measures a temperature using a magnitude of electromotive force generated in proportion to a temperature difference between two contacts. When the temperature sensor 140 is a thermocouple, one end of the temperature sensor 140 may contact the cooling element 150 and the other end may contact the semiconductor package 120. Since a temperature of the cooling element 150 is controlled and recognized by the user, the temperature of the semiconductor package 120 may be measured by measuring a magnitude of electromotive force generated in the temperature sensor 140. Contact may mean both direct contact and indirect contact through other materials. For example, although not shown, an adhesive material or TIM may be further interposed between the temperature sensor 140 and the semiconductor package 120 and/or between the temperature sensor 140 and the cooling element 150.

In a variation of the illustrated embodiment, instead of the temperature sensor 140 being disposed over the upper surface of the semiconductor package 120 as described above, a device capable of sensing and/or measuring the temperature of the semiconductor package 120 in any way, may be mounted inside the semiconductor package 120 or on the outside. For example, the device capable of sensing and/or measuring the temperature of the semiconductor package 120 may be disposed in the substrate 110.

The temperature sensor 140 may be connected to the substrate 110 through an interconnector 142 to supply temperature information of the semiconductor package 120 to the substrate 110. The interconnector 142 may be a bonding wire having one end connected to the temperature sensor 140 and the other end connected to the substrate 110. However, the present disclosure is not limited thereto, and various types of electrical interconnectors may be used as the interconnector 142.

The cooling element 150 may contact the Peltier element 130. The cooling element 150 may be formed on the Peltier element 130 and may be in contact with the Peltier element either directly or indirectly. Furthermore, the cooling element 150 may contact the temperature sensor 140. The contact with the temperature sensor may also be direct contact or indirect contact through some other suitable material. For example, although not shown, an adhesive material or TIM may be further interposed between the cooling element 150 and the Peltier element 130 and/or between the cooling element 150 and the temperature sensor 140.

The cooling element 150 may be configured to receive and flow a cooling liquid from the outside. For example, the cooling element 150 may be a liquid jacket. Here, as the cooling liquid, a liquid that can reach a cryogenic temperature, for example, −196° C., may be used. For example, liquid nitrogen or liquid helium may be used as the cooling liquid.

The cooling element 150 may lower the temperature of the heat generating portion P1 by contacting the heat generating portion P1 of the Peltier element 130. As described above, the temperature of the heat generating portion P1 of the Peltier element 130 may be higher than the temperature of the heat absorbing portion P2. Here, a maximum temperature difference between the heat generating portion P1 and the heat absorbing portion P2 may be 70° C. or higher. Accordingly, even when the temperature of the heat absorbing portion P2 is required to be lowered to a target temperature of the semiconductor package 120 or to a temperature similar to the target temperature, the temperature of the heat generating portion P1 may be higher than the target temperature. For example, if the temperature of the heat generating portion P1 is lowered to a range between −120° C. to −130° C., for example, to −126° C., the temperature of the heat absorbing portion P2 may be lowered to the target temperature, for example, to −196° C.

Meanwhile, the lower the temperature of the heat generating portion P1 of the Peltier element 130, the lower the temperature of the heat absorbing portion P2 of the Peltier element 130. Accordingly, the temperature of the semiconductor package 120 in contact with the heat absorbing portion P2 may be reduced. A first method for reducing the temperature of the heat generating portion P1 of the Peltier element 130 may be to increase a flow rate of the cooling liquid flowing through the cooling element 150. A second method for reducing the temperature of the heat generating portion P1 of the Peltier element 130 may be to increase a power applied to the Peltier element 130. Both the first method and the second method may be used, or one of them may be used.

In the present disclosure, since the Peltier element 130 is interposed between the semiconductor package 120 and the cooling element 150, the cooling element 150 may be driven until the heat generating portion P1 of the Peltier element 130 reaches its target temperature, not until the semiconductor package 120 reaches its target temperature. Accordingly, a cooling degree of the cooling element 150 may be reduced. In other words, the flow rate of the cooling liquid flowing through the cooling element 150 may be reduced, or the power applied to the Peltier element 130 may be reduced. As a result, it may be possible to reduce the cost by reducing the amount of cooling liquid used, or by reducing power consumption due to the reduction of the power applied to the Peltier element 130.

To drive the cooling element 150, the cooling liquid supply pipe 160 may have one end connected to the cooling element 150 to supply the cooling liquid to the cooling element 150, and the cooling liquid recovery pipe 170 may have one end connected to the cooling element 150 to recover the cooling liquid from the cooling element 150. The other end of each of the cooling liquid supply pipe 160 and the cooling liquid recovery pipe 170 may be connected to a cooling liquid storage unit (not shown). The cooling liquid may generate a flow in the cooling element 150 by entering the cooling element 150 from the cooling liquid supply pipe 160 and exiting through the cooling liquid recovery pipe 170.

The other end of the cooling liquid supply pipe 160 may be connected to a flow rate control valve 162 for adjusting the flow rate of the supplied cooling liquid. The flow rate of the cooling liquid supplied to the cooling element 150 may decrease or increase depending on a degree of opening of the flow rate control valve 162. When the flow rate control valve 162 is completely closed, the supply of cooling liquid to the cooling element 150 may be stopped.

The semiconductor module 100 described above may be connected to the temperature control device 200 for controlling a temperature of the semiconductor module 100. For reference, the temperature of the semiconductor module 100 may be the same as or substantially proportional to the temperature of the semiconductor package 120, and the temperature of the semiconductor package 120 may be substantially proportional to the temperature of the heat generating portion P1 of the Peltier element 130. Accordingly, adjusting the temperature of the semiconductor module 100 may mean adjusting the temperature of the semiconductor package 120 and/or adjusting the temperature of the heat generating portion P1 of the Peltier element 130.

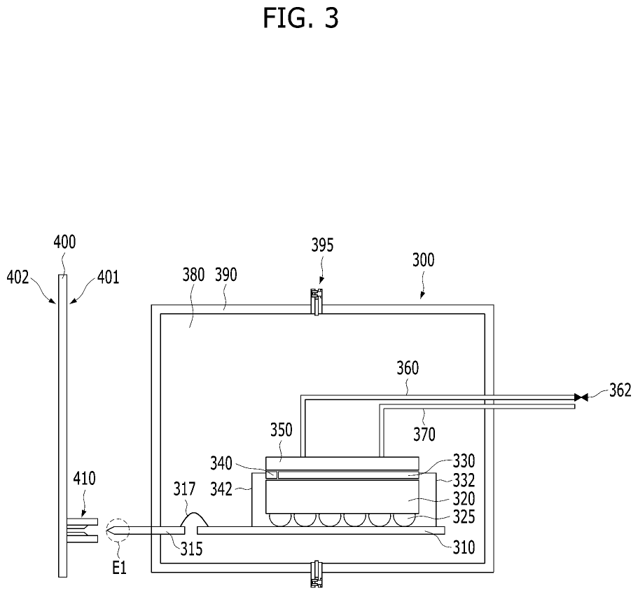

The temperature control device 200 may receive the temperature information of the semiconductor package 120 from the temperature sensor 140. More specifically, the temperature information of the semiconductor package 120 may be transferred from the temperature sensor 140 to the substrate 110 through the interconnector 142. Since the substrate 110 has various circuits and/or wiring structures, the temperature information may be transferred to the outside of the substrate 110 and/or to the outside of the semiconductor module 100 through the substrate 110. The temperature control device 200 may be electrically connected to the substrate 110 to receive this temperature information. An electrical connection of the temperature control device 200 and the substrate 110 may be made in various ways. For example, an electrical connection between a temperature control device and a substrate may be made in a manner as described later in reference to FIG. 3.

The temperature control device 200 may determine whether the semiconductor package 120 reaches a target temperature, for example, a cryogenic temperature from the temperature information of the semiconductor package 120.

As a result of the determination, if it is determined that the temperature of the semiconductor package 120 is not lowered to the target temperature, that is, for example, if it is determined that the temperature of the semiconductor package 120 is higher than the targeted cryogenic temperature, a signal for increasing the flow rate of the cooling liquid, or a signal for increasing the power of the Peltier element 130, or both may be transferred to the semiconductor module 100. More specifically, the signal for increasing the flow rate of the cooling liquid may be transferred to the flow rate control valve 162 and open the flow rate control valve 162, as necessary. In addition, the signal for increasing the power of the Peltier element 130 may be transferred to the substrate 110, particularly, the power supply circuit (not shown) of the substrate 110. The power supply circuit of the substrate 110 may receive this signal and transfer the increased power to the Peltier element 130 through the interconnector 132.

On the other hand, as a result of the determination of the temperature control device 200, when it is determined that the semiconductor package 120 reaches the target temperature, that is, the cryogenic temperature, a signal for reducing the flow rate of the cooling liquid, a signal for reducing the power of the Peltier element 130, or both may be transferred to the semiconductor module 100. More specifically, the signal for reducing the flow rate of the cooling liquid may be transferred to the flow rate control valve 162 and close the flow rate control valve 162, as necessary. In addition, the signal for reducing the power of the Peltier element 130 may be transferred to the substrate 110, particularly, the power supply circuit of the substrate 110. The power supply circuit of the substrate 110 may receive this signal and transfer the reduced power to the Peltier element 130 through the interconnector 132.

The temperature control device 200 may receive the temperature information of the semiconductor package 120 again from the semiconductor module 100 in which the flow rate of the cooling liquid supplied is changed or the power of the Peltier element 130 is changed, and determine whether the target temperature is reached or maintained. According to a result of the determination, the temperature control device 200 may transfer a signal to increase or decrease the flow rate of the cooling liquid and/or a signal to increase or decrease the power of the Peltier element 130 to the semiconductor module 100 again.

The temperature control system described above may have the following advantages.

First, by adding a Peltier element and a cooling element on a semiconductor package, the semiconductor package can be cooled without changing the semiconductor package and the semiconductor module. Therefore, it may be easy to implement a cryogenic system.

Further, by interposing the Peltier element between the semiconductor package and the cooling element and arranging the heat generating portion and the heat absorbing portion of the Peltier element on a cooling element side and a semiconductor package side, respectively, a degree of cooling requirement of the cooling element can be reduced. Therefore, it may be possible to reduce the amount of the cooling liquid used and to reduce the power of the Peltier element. As a result, cost and efficiency can be advantageous.

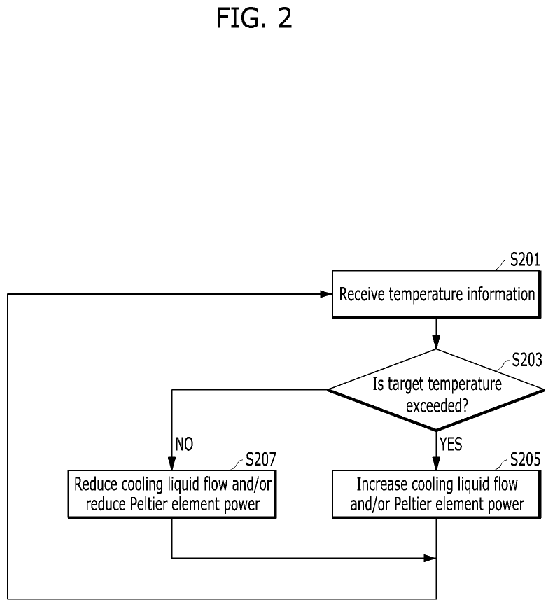

FIG. 2 is a flow chart of a temperature control method of the temperature control device 200 of the system of FIG. 1.

Referring to FIG. 2, the temperature control device 200 may receive the temperature information of the semiconductor package 120 from the semiconductor module 100, and more specifically from the temperature sensor 140 (S201). For reference, when receiving the temperature information, the Peltier element 130 and the cooling element 150 may be driving. For example, a predetermined power may be applied to the Peltier element 130 and a cooling liquid having a predetermined flow rate may flow through the cooling element 150.

Subsequently, the temperature control device 200 may determine whether the semiconductor package 120 has reached the target temperature, for example, the cryogenic temperature, based on the received temperature information (S203).

As a result of the determination in step S203, if it is determined that the semiconductor package 120 exceeds the target temperature, that is, if it is determined that the semiconductor package 120 is not sufficiently cooled (Yes in S203), the temperature control device 200 may increase the flow rate of the cooling liquid, the power of the Peltier element 130, or both (S205). That is, the temperature control device 200 may transfer a signal to increase the flow rate of the cooling liquid, a signal to increase the power of the Peltier element 130, or both to the semiconductor module 100.

On the other hand, as a result of the determination in step S203, if it is determined that the semiconductor package 120 reaches the target temperature (No in S203), that is, if it is determined that the semiconductor package 120 is sufficiently cooled, the temperature control device 200 may reduce the flow rate of the cooling liquid, the power of the Peltier element 130, or both (S207). That is, the temperature control device 200 may transfer a signal for reducing the flow rate of the cooling liquid, a signal for reducing the power of the Peltier element 130, or both to the semiconductor module 100.

The above steps S201 to S207 may be repeatedly performed. Furthermore, steps S201 to S207 may be repeatedly performed at regular time intervals. For example, after performing step S205 or step S207, the temperature change of the semiconductor package 120 may be sufficiently made due to the change of the flow rate of the cooling liquid or the change of the power of the Peltier element 130, and then the temperature of the semiconductor package 120 may be maintained. Step S201 may be performed again after the temperature of the semiconductor package 120 is maintained.

Meanwhile, as described above, even if a semiconductor module is implemented to have a cryogenic temperature, heat transfer between the semiconductor module and surroundings thereof may be readily blocked in order to efficiently maintain the cryogenic temperature. This will be described as an example in FIG. 3 below. In addition, in FIG. 3, a connection between the semiconductor module and an external, for example, a temperature control device will be described as an example. In the description of FIG. 3, differences from the above-described embodiment will be mainly described.

FIG. 3 is a simplified schematic illustrating a temperature control system according to another embodiment of the present disclosure.

Referring to FIG. 3, a temperature control system according to another embodiment of the present disclosure may include a semiconductor module 300 that includes substantially the same components as those of the semiconductor module 100 described above. That is, the semiconductor module 300 may include a substrate 310, a semiconductor package 320 disposed over the substrate 310 and electrically connected to the substrate 310 through a connection terminal 325, a Peltier element 330 disposed over the semiconductor package 320 and electrically connected to the substrate 310 through an interconnector 332 while having a heat absorbing portion contacting the semiconductor package 320, a temperature sensor 340 disposed over the semiconductor package 320 and electrically connected to the substrate 310 through an interconnector 342 while being disposed in a region where the Peltier element 330 is not formed, a cooling element 350 disposed over the Peltier element 330 and the temperature sensor 340 and contacting a heat generating portion of the Peltier element 330, and a cooling liquid supply pipe 360 and a cooling liquid recovery pipe 370 connected to the cooling element 350. An end of the cooling liquid supply pipe 360 may be connected to a flow rate control valve 362.

Furthermore, in addition to the above components 310, 325, 320, 330, 332, 340, 342, 350, 360, and 370, the semiconductor module 300 may further include a heat-blocking material 380 surrounding the components 310, 325, 320, 330, 332, 340, 342, 350, 360, and 370 and a heat-blocking case 390.

The heat-blocking material 380 may be made of any material as long as it serves to block heat transfer between the semiconductor package 320 which has been cooled and the outside. As an example, the heat-blocking material 380 may include a heat-blocking paint. The heat-blocking paint may be a paint in which vacuum ceramic spheres and silicon micro-spheres are mixed. The heat-blocking paint may be coated on surfaces of the components 310, 325, 320, 330, 332, 340, 342, 350, 360, and 370 in a thickness of several to several tens of mm.

The heat-blocking case 390 may have a shape surrounding the components 310, 325, 320, 330, 332, 340, 342, 350, 360, and 370, and heat-blocking material 380. In order to efficiently block heat transfer between the cooled semiconductor package 320 and the outside, the heat-blocking case 390 may be a vacuum case in which a space between inner and outer walls of the vacuum case is in a vacuum state. In order to seal the components 310, 325, 320, 330, 332, 340, 342, 350, 360, and 370, and the heat-blocking material 380, the heat-blocking case 390 may be configured to include two (or more) pieces and a fastening portion 395 for joining these pieces together. In the embodiment of FIG. 3, the heat-blocking case 390 may include a left piece and a right piece, and may include two fastening portions 395 for coupling the left piece and the right piece at an upper center and a lower center, respectively. The fastening portion 395 or portions may be formed by assembling various components such as an O-ring, a screw, or the like.

The cooling liquid supply pipe 360 and the cooling liquid recovery pipe 370 may protrude out of the heat-blocking case 390 to be connected to an external cooling liquid storage unit (not shown). To this end, openings through which the cooling liquid supply pipe 360 and the cooling liquid recovery pipe 370 pass may be formed in the heat-blocking case 390. Here, since the heat-blocking material 380 is only present inside the heat-blocking case 390, portions of the cooling liquid supply pipe 360 and the cooling liquid recovery pipe 370, which are outside the heat-blocking case 390, may not be coated with the heat-blocking material 380. In addition, the flow rate control valve 362 may be connected to the end of the cooling liquid supply pipe 360 and exist outside the heat-blocking case 390.

Meanwhile, the substrate 310 needs to be connected to an external component, such as the temperature control device 200 of FIG. 1. However, if the substrate 310 protrudes out of the heat-blocking case 390 to connect the substrate 310 and the external component, heat transfer between the semiconductor package 320 and the outside may occur through the substrate 310. In order to prevent this, in the present embodiment, the substrate 310 may exist in the heat-blocking case 390, and be electrically connected to the external component using an additional substrate 315. The additional substrate 315 may be electrically connected to the substrate 310 while physically separated from the substrate 310.

The additional substrate 315 may be a substrate having circuits and/or wiring structures for electric signal transmission. For example, the additional substrate 315 may be a printed circuit board. The additional substrate 315 may be disposed at one side of the substrate 310, for example, at a left side, but spaced apart from the substrate 310. The additional substrate 315 may be electrically connected to the substrate 310 through any suitable wire such as, for example, a bonding wire 317. This way, the substrate 310 and the additional substrate 315 may be electrically connected, but heat transfer between the substrate 310 and the additional substrate 315 may be prevented. Signals, powers, or the like of the substrate 310 may be transferred to the outside through the bonding wire 317 and the circuits and/or wiring structures of the additional substrate 315.

A portion of the additional substrate 315, which is adjacent to the substrate 310, and the bonding wire 317 connected to the portion of the additional substrate 315 may be disposed in the heat-blocking case 390. On the other hand, the rest of the additional substrate 315 may protrude out of the heat-blocking case 390. To this end, an opening through which the rest of the additional substrate 315 passes may be formed in the heat-blocking case 390. The heat-blocking material 380 may not be coated to the rest of the additional substrate 315 which is outside of the heat-blocking case 380.

The semiconductor module 300, while having all the advantages of the above-described embodiment of FIG. 1, may further have the following effects.

Because of the use of the heat-blocking material 380, the heat-blocking case 390, and the additional substrate 315 which is separated from the substrate 310, heat transfer between the semiconductor module 300 and the outside can be effectively blocked. That is, since the semiconductor module 300 is prevented from being affected by an external high temperature, cooling efficiency of the semiconductor module 300 may be further increased. In addition, since the outside is prevented from being affected by a low temperature of the semiconductor module 300, it may be possible to prevent formation of frost or dew on the outside. As a result, only the semiconductor module 300 may be locally cooled.

In addition, since the method of using the heat-blocking material 380, the heat-blocking case 390, and the additional substrate 315 separated from the substrate 310 does not require modification of the semiconductor module 300 and a temperature control system including the same, it may be easier to implement in a cryogenic system employed, for example, in a quantum computer.

Meanwhile, the semiconductor module 300 may be electrically connected to another substrate 400. The substrate 400 may include various circuits and/or components so that the semiconductor module 300 is mounted thereon and performs a predetermined function. As an example, although not shown, the substrate 400 may include circuits and/or components that perform the same functions as the temperature control device 200 of FIG. 1 described above. The substrate 400 may be different from the substrate 310 for forming a semiconductor package and/or module. For example, the substrate 310 may be a PCB for a module, and the substrate 400 may be a motherboard.

The substrate 400 may have a plate shape. That is, the substrate 400 may have a first plane 401 and a second plane 402 positioned opposite to each other, and side surfaces connecting them to each other. FIG. 3 is a cross-sectional simplified schematic showing a side surface of the substrate 400. In FIG. 3, the first plane 401 of the substrate 400 may be disposed on the right side to face the semiconductor module 310, and the second plane 402 may be disposed on the left side.

The substrate 400 and the additional substrate 315 of the semiconductor module 300, in particular, the rest of the additional substrate 315 protruding out of the heat-blocking case 390 may be electrically connected to each other in various ways. In this embodiment, the semiconductor module 300 and the substrate 400 may be electrically connected to each other by using a module socket 410 formed in the substrate 400. The module socket 410 may be a structure for mounting the semiconductor module 300, and may be configured to electrically connect the semiconductor module 300 and the substrate 400 and physically support the semiconductor module 300. The module socket 410 may be formed on the first plane 401 of the substrate 400, which faces the semiconductor module 300, and may protrude toward the semiconductor module 300, for example, toward a right side of the substrate 400. The module socket 410 may protrude in a direction perpendicular to the first plane 401 of the substrate 400. The module socket 410 may be configured to accommodate an end of the additional substrate 315 (see E1). For example, the module socket 410 may include a cavity adapted to receive the end E1 of the additional substrate 315 (see E1).

Meanwhile, FIG. 3 is a cross-sectional simplified schematic, so it shows a side surface of the semiconductor module 300, particularly side surfaces of the substrate 310 and the additional substrate 315. For reference, each of the substrate 310 and the additional substrate 315 may have a plate shape. Both planes of the substrate 310 and both planes of the additional substrate 315 may be perpendicular to the first plane 401 of the substrate 400. That is, in FIG. 3, both planes of the substrate 310 correspond to upper and lower surfaces of the substrate 310, and both planes of the additional substrate 315 correspond to upper and lower surfaces of the additional substrate 315. In particular, both planes of the additional substrate 315 may be perpendicular to the first plane 401 of the substrate 400 to allow the end E1 of the additional substrate 315 to be inserted into the module socket 410. This is because, as described above, the module socket 410 protrudes in the direction perpendicular to the first plane 401 of the substrate 400. The end E1 of the additional substrate 315 may have a shape suitable for insertion and coupling into the module socket 410. For example, when a groove having a width which gradually narrows is formed inside the module socket 410, the end E1 of the additional substrate 315 may have a shape the same as or similar to the groove, that is, a shape in which a width thereof gradually narrows towards its tip. For reference, FIG. 3 shows a state before the end E1 of the additional substrate 315 of the semiconductor module 300 is inserted into the module socket 410 of the substrate 400. In this state, the end E1 of the additional substrate 310 and the module socket 410 may be aligned with each other for insertion.

When the end E1 of the additional substrate 315 of the semiconductor module 300 is inserted into and coupled to the module socket 410 of the substrate 400, the semiconductor module 300 and the substrate 400 are electrically connected with each other. Signals between the semiconductor module 300 and the substrate 400 may then be transferred to each other through the substrate 310, the bonding wire 317, the additional substrate 315, and the module socket 410. The signals may include the temperature information of the semiconductor package 320, a signal for increasing the power of the Peltier element 330, or the like. For reference, a signal for increasing the flow rate of the cooling liquid supplied to the cooling element 350 may be transferred to the flow rate control valve 362 through another path without using the additional substrate 315 and the substrate 310.

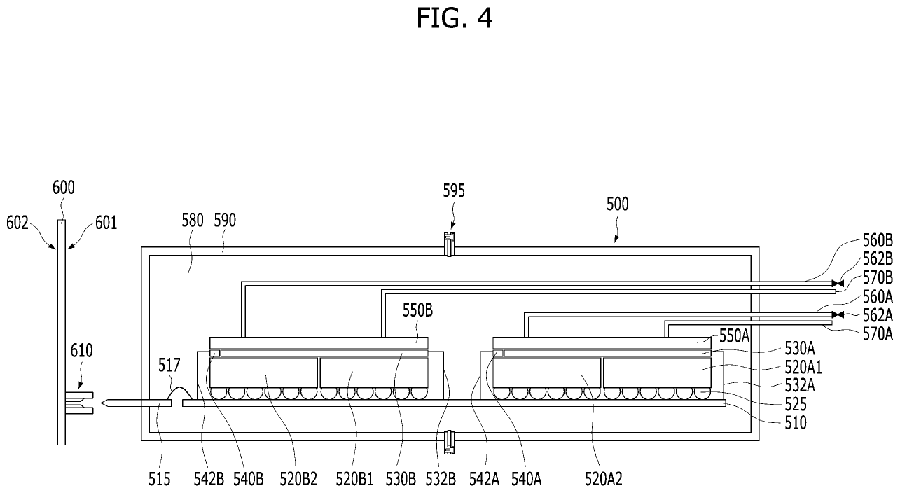

Meanwhile, in the above-described embodiments, a case where a semiconductor module includes one semiconductor package and one cooling element corresponding thereto is described, but the present disclosure is not limited thereto. In another embodiment, a semiconductor module may include a plurality of semiconductor packages and/or a plurality of cooling elements. In addition, one cooling element may cool two or more semiconductor packages. An example of this arrangement will be described with reference to FIG. 4. In the description of FIG. 4, differences from the above-described embodiments will be mainly described.

FIG. 4 is a simplified schematic illustrating a temperature control system according to another embodiment of the present disclosure.

Referring to FIG. 4, a temperature control system according to another embodiment of the present disclosure may include a substrate 510, semiconductor packages 520A1, 520A2, 520B1, and 520B2 disposed over the substrate 510 and electrically connected to the substrate 510 through connection terminals 525. The system may also include Peltier elements 530A and 530B disposed over the semiconductor packages 520A1, 520A2, 520B1, and 520B2 and electrically connected to the substrate 510 through interconnects 532A and 532B while having heat absorbing portions contacting the semiconductor packages 520A1, 520A2, 520B1, and 520B2, temperature sensors 540A and 540B disposed over the semiconductor packages 520A1, 520A2, 520B1, and 520B2 in a region where the Peltier elements 530A and 530B are not formed. The temperature sensors 540A and 540B may be electrically connected to the substrate 510 through interconnects 542A and 542B. The system my further include cooling elements 550A and 550B disposed over the Peltier elements 530A and 530B and the temperature sensors 540A and 540B and which contact heat generating portions of the Peltier elements 530A and 530B. Cooling liquid supply pipes 560A and 560B and cooling liquid recovery pipes 570A and 570B may be connected to the cooling elements 550A and 550B. Ends of the cooling liquid supply pipes 560A and 560B may be connected to flow rate control valves 562A and 562B. Furthermore, the semiconductor module 500 may further include a heat-blocking material 580 and a heat-blocking case 590. The heat-blocking case 590 may include a plurality of pieces and fastening portions 595 that couples them. Furthermore, the semiconductor module 500 may further include an additional substrate 515. The additional substrate 515 may be physically separated from the substrate 510 while being electrically connected to the substrate 510, and protrude out of the heat-blocking case 590. The additional substrate 515 may be electrically connected to the substrate 510, for example, by a bonding wire 517.

In the semiconductor module 500 as described above, as an example, two cooling elements 550A and 550B, that is, a first cooling element 550A and a second cooling element 550B may be employed. A first cooling liquid supply pipe 560A and a first cooling liquid recovery pipe 570A may be connected to the first cooling element 550A, and a second cooling liquid supply pipe 560B and a second cooling liquid recovery pipe 570B may be connected to the second cooling element 550B.

Two or more semiconductor packages may be controlled by the two cooling elements 550A and 550B. For example, two first semiconductor packages 520A1 and 520A2 may be controlled by the first cooling element 550A, and two second semiconductor packages 520B1 and 520B2 may be controlled by the second cooling element 550B.

One first Peltier element 530A and one first temperature sensor 540A may be disposed between the first cooling element 550A and the two first semiconductor packages 520A1 and 520A2. This is because the two first semiconductor packages 520A1 and 520A2 may be controlled to be the same temperature as each other by the first cooling element 550A. In this embodiment, the first temperature sensor 540A may be located on a left first semiconductor package 520A2. However, in another embodiment, the first temperature sensor 540A may be located on a right first semiconductor package 520A1. Similarly, one second Peltier element 530B and one second temperature sensor 540B may be disposed between the second cooling element 550B and the two second semiconductor packages 520B1 and 520B2.

Thus, cooling efficiency can be increased by appropriately adjusting the number of cooling elements and the number of semiconductor packages controlled by each cooling element.

Meanwhile, the system of the present embodiment may further include a substrate 600 connected to the semiconductor module 500. The substrate 600 may include a first plane 601 facing the semiconductor module 500 and a second plane 602 positioned opposite thereto, and a module socket 610 disposed on the first plane 601. The semiconductor module 500 may be electrically connected to the substrate 600 by a method in which the end of the additional substrate 515 is coupled to the module socket 610.

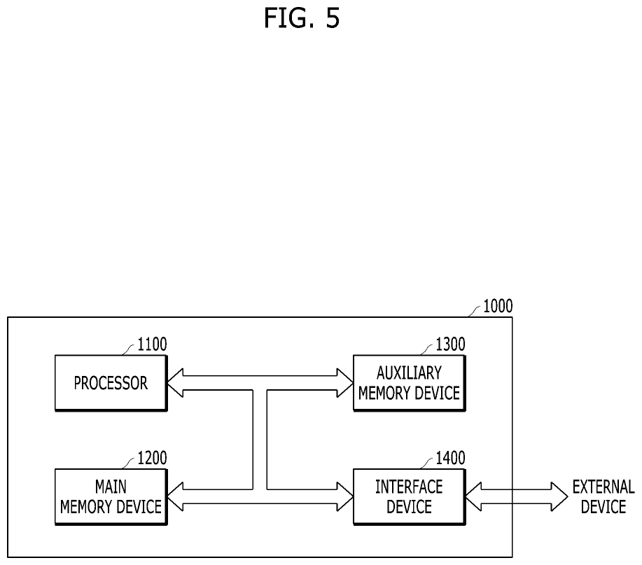

FIG. 5 is simplified schematic illustrating a temperature control system 1000 according to another embodiment of the present disclosure.

Referring to FIG. 5, the temperature control system 1000 as an apparatus for processing data may perform input, processing, output, communication, storage, etc. to conduct a series of manipulations for data. The system 1000 may include a processor 1100, a main memory device 1200, an auxiliary memory device 1300, an interface device 1400, and the like. The system 1000 of the present embodiment may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and the like. In particular, the system 1000 of the present embodiment may be a quantum computer requiring a cryogenic memory, and the like.

The processor 1100 may decode inputted commands, processes various operations, e.g., comparisons, etc. for the data stored in the system 1000, and control these operations. In particular, the processor 1100 may include a circuit controlling a temperature of the main memory device 1200 or the auxiliary memory device 1300.

The main memory device 1200 is a storage which can temporarily store, call and execute program codes or data from the auxiliary memory device 1300 when programs are executed, and can retain memorized contents even when power supply is cut off. The auxiliary memory device 1300 is a memory device for storing program codes or data. While the speed of the auxiliary memory device 1300 is slower than the main memory device 1200, the auxiliary memory device 1300 can store a larger amount of data. The main memory device 1200 or the auxiliary memory device 1300 may include one or more of the above-described semiconductor modules in accordance with the embodiments. For example, the main memory device 1200 or the auxiliary memory device 1300 may include: a substrate; a semiconductor package disposed over the substrate; a Peltier element disposed over the semiconductor package and having a heat absorbing portion and a heat generating portion, the heat absorbing portion being adjacent to the semiconductor package and the heat generating portion being adjacent to a cooling element; and the cooling element disposed over the Peltier element. Through this, efficient and local cooling of the main memory device 1200 or the auxiliary memory device 1300 may be possible, and implementation of the main memory device 1200 or the auxiliary memory device 1300 may be easy. As a consequence, implementation of system 1000 may be easy.

The interface device 1400 may perform exchange of commands and data between the system 1000 and an external device. The interface device 1400 may be a keypad, a keyboard, a mouse, a speaker, a mike, a display, various human interface devices (HIDs), a communication device, and the like.

Although the present disclosure is described via various embodiments for illustrative purposes, it will be apparent to those skilled in the art that various changes and modifications may be made without departing from the spirit and scope of the present disclosure as defined in the following claims.

What is claimed is:

1. A semiconductor module comprising:
a semiconductor package disposed over a substrate;
a Peltier element disposed over the semiconductor package and having a heat absorbing portion and a heat generating portion, the heat absorbing portion being adjacent to the semiconductor package and the heat generating portion being adjacent to a cooling element; and
the cooling element disposed over the Peltier element.

2. The semiconductor module according to claim 1, wherein the cooling element is driven so that the heat generating portion of the Peltier element has a temperature higher than a target cooling temperature of the semiconductor package.

3. The semiconductor module according to claim 1, wherein a target cooling temperature of the semiconductor package is controlled according to a flow rate of a cooling liquid flowing through the cooling element.

4. The semiconductor module according to claim 3, further comprising:
a cooling liquid supply pipe having one end connected to the cooling element and supplying the cooling liquid to the cooling element; and
a cooling liquid recovery pipe having one end connected to the cooling element and recovering the cooling liquid from the cooling element.

5. The semiconductor module according to claim 4, further comprising:
a flow rate control valve connected to the other end of the cooling liquid supply pipe and controlling the flow rate of the cooling liquid supplied to the cooling element.

6. The semiconductor module according to claim 1, wherein a target cooling temperature of the semiconductor package is controlled by controlling a power supplied to the Peltier element.

7. The semiconductor module according to claim 6, further comprising:
an interconnector electrically connecting the Peltier element and the substrate,
wherein the Peltier element receives the power from the substrate through the interconnector.

8. The semiconductor module according to claim 1,
wherein the Peltier element occupies a portion of a space between the semiconductor package and the cooling element, and
a temperature sensor is disposed in a space between the semiconductor package and the cooling element which is not occupied by the Peltier element.

9. The semiconductor module according to claim 8, wherein the temperature sensor includes a thermocouple.

10. The semiconductor module according to claim 8, further comprising:
an interconnector electrically connecting the temperature sensor and the substrate,
wherein temperature information measured by the temperature sensor is transferred to the substrate through the interconnector.

11. The semiconductor module according to claim 1, further comprising:
a heat-blocking case surrounding a stacked structure of the substrate, the semiconductor package, the Peltier element and the cooling element.

12. The semiconductor module according to claim 11, further comprising:
a heat-blocking material formed on a surface of the stacked structure and filling at least a portion of an inside of the heat-blocking case.

13. The semiconductor module according to claim 12, wherein the heat-blocking material includes a heat-blocking paint in which vacuum ceramic spheres and silicone micro-spheres are mixed.

14. The semiconductor module according to claim 11, further comprising:
an additional substrate electrically connected to the substrate and physically separated from the substrate, wherein a portion of the additional substrate protrudes out of the heat-blocking case.

15. The semiconductor module according to claim 14, wherein the semiconductor module is connected to an external component through the portion of the additional substrate.

16. The semiconductor module according to claim 14, wherein the substrate and the additional substrate are electrically connected by a bonding wire.

17. The semiconductor module according to claim 1, wherein the cooling element includes a plurality of cooling elements, and
wherein the semiconductor package includes a plurality of semiconductor packages corresponding to the plurality of cooling elements, respectively.

18. The semiconductor module according to claim 1, wherein the cooling element includes a plurality of cooling elements, and
each of the plurality of cooling elements is disposed over two or more semiconductor packages.

19. A semiconductor module comprising:
a substrate including a power circuit;
a semiconductor package disposed on a first substrate;
a Peltier element having a heat absorbing portion and a heat generation portion;
a cooling element; and
a second substrate physically separated from the first substrate and electrically connected with the first substrate for electrically connecting the semiconductor module to an external component,
wherein the heat absorbing portion is in contact with the semiconductor package, and the heat generating portion is in contact with the cooling element, and a target cooling temperature of the semiconductor package is controlled according to a flow rate of a cooling liquid flowing through the cooling element or a power supplied to the Peltier element from the power circuit.
